(19) United States
(12) Patent Application Publication
(10) Pub. No.: US 2022/0084842 A1
(43) Pub. Date: Mar. 17, 2022

(54) ANTIFRAGILE SYSTEMS FOR SEMICONDUCTOR PROCESSING EQUIPMENT USING MULTIPLE SPECIAL SENSORS AND ALGORITHMS

(71) Applicant: Applied Materials, Inc., Santa Clara, CA (US)

(72) Inventors: Martin Hilkene, Gilroy, CA (US); Kartik Shah, Santa Clara, CA (US); Stephen Moffatt, St. Brelade (JE)

(21) Appl. No.: 17/019,061

(22) Filed: Sep. 11, 2020

(51) Int. Cl. H01L 21/67; G01F 1/86

(52) U.S. Cl. CPC H01L 21/67017; G01F 1/86; H01L 21/67248; H01L 21/67253

(57) ABSTRACT

Embodiments disclosed herein include a processing tool and methods of using the processing tool. In an embodiment, the processing tool comprises a chamber, and a cartridge for flowing one or more processing gasses into the chamber from a plurality of gas sources. In an embodiment, the processing tool further comprises a mass flow controller for each of the plurality of gas sources, and a mass flow meter between the gas sources and the cartridge. In an embodiment, the processing tool further comprises a first pressure gauge between the mass flow meter and the cartridge, a second pressure gauge fluidically coupled to the chamber, and an exhaust line coupled to the chamber.

### BACKGROUND

### 1) Field

Embodiments of the present disclosure pertain to the field of semiconductor processing and, in particular, to a process chamber with control loop sensors and witness sensors.

### 2) Description of Related Art

Semiconductor wafer processing has been increasing in complexity as semiconductor devices continue to progress to smaller feature sizes. A given process may include many different processing parameters (i.e., knobs) that can be individually controlled in order to provide a desired outcome on the wafer. For example, the desired outcome on the wafer may refer to a feature profile, a thickness of a layer, a chemical composition of a layer, or the like. As the number of knobs increase, the theoretical process space available to tune and optimize the process grows exceedingly large.

Additionally, once the final processing recipe has been developed, chamber drift during many iterations of the process for different wafers may result in changes to the outcome on the wafer. Chamber drift may be the result of erosion of consumable portions of the chamber, degradation of components (e.g., sensors, lamps, etc.), deposition of byproduct films over surfaces, or the like. Accordingly, additional tuning is needed even after the extensive recipe development process.

### SUMMARY

Embodiments disclosed herein include a processing tool and methods of using the processing tool. In an embodiment, the processing tool comprises a chamber, and a cartridge for flowing one or more processing gasses into the chamber from a plurality of gas sources. In an embodiment, the processing tool further comprises a mass flow controller for each of the plurality of gas sources, and a mass flow meter between the gas sources and the cartridge. In an embodiment, the processing tool further comprises a first pressure gauge between the mass flow meter and the cartridge, a second pressure gauge fluidically coupled to the chamber, and an exhaust line coupled to the chamber.

In an embodiment, a processing tool comprises a physical tool, a virtual sensor module, and a data model. In an embodiment, the physical tool comprises control loop sensors, and witness sensors. In an embodiment, the virtual sensor module receives control loop sensor data and witness sensor data as inputs, and the virtual sensor module outputs virtual sensor data. In an embodiment, the data model comprises a statistical model, and a physical model. In an embodiment, the virtual sensor data is provided to the data model, and the data model is configured to provide a control effort to the physical tool based, at least in part, on the virtual sensor data.

In an embodiment, a method of determining chamber drift is provided. In an embodiment, the method comprises providing hardware inputs and process parameter inputs into a physical chamber and a data model, and collecting witness sensor outputs from the physical chamber. In an embodiment, the method further comprises generating virtual witness sensor outputs from the data model, and comparing the witness sensor outputs with the virtual witness sensor outputs.

### BRIEF DESCRIPTION OF THE DRAWINGS

FIG. 1 is a block diagram of a semiconductor processing tool that utilizes a set of control loop sensors, in accordance with an embodiment of the present disclosure.

FIG. 2A is a block diagram of a semiconductor processing tool that utilizes a set of control loop sensors and a set of witness sensors, in accordance with an embodiment of the present disclosure.

FIG. 2B is a block diagram of a semiconductor processing tool that utilizes a set of control loop sensors and a set of witness sensors that include an array of temperature sensors, in accordance with an embodiment of the present disclosure.

FIG. 3 is a perspective illustration of the physical chamber of a semiconductor processing tool, in accordance with an embodiment of the present disclosure.

FIG. 4A is a block diagram of a semiconductor processing tool that includes a data model and witness sensors, in accordance with an embodiment of the present disclosure.

FIG. 4B is a flowchart of a method for using control loop sensors and witness sensors to provide feedback control of a processing tool, in accordance with an embodiment.

FIG. 4C is a schematic illustration of a processing tool with witness sensors, in accordance with an embodiment

FIG. 4D is a schematic illustration of a processing tool with witness sensors and a mass flow controller to control a first pressure upstream of the cartridge, in accordance with an embodiment.

FIG. 5A is a flowchart of a method for using a data model to detect chamber drift of a semiconductor processing tool, in accordance with an embodiment of the present disclosure.

FIG. 5B is a flowchart of a method for utilizing virtual sensor data and metrology data to confirm the accuracy of a data model in a semiconductor processing tool, in accordance with an embodiment of the present disclosure.

FIG. 6 illustrates a block diagram of an exemplary computer system, in accordance with an embodiment of the present disclosure.

### DETAILED DESCRIPTION

Process chambers with control loop sensors, witness sensors, and a data model are described herein. In the following description, numerous specific details are set forth, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

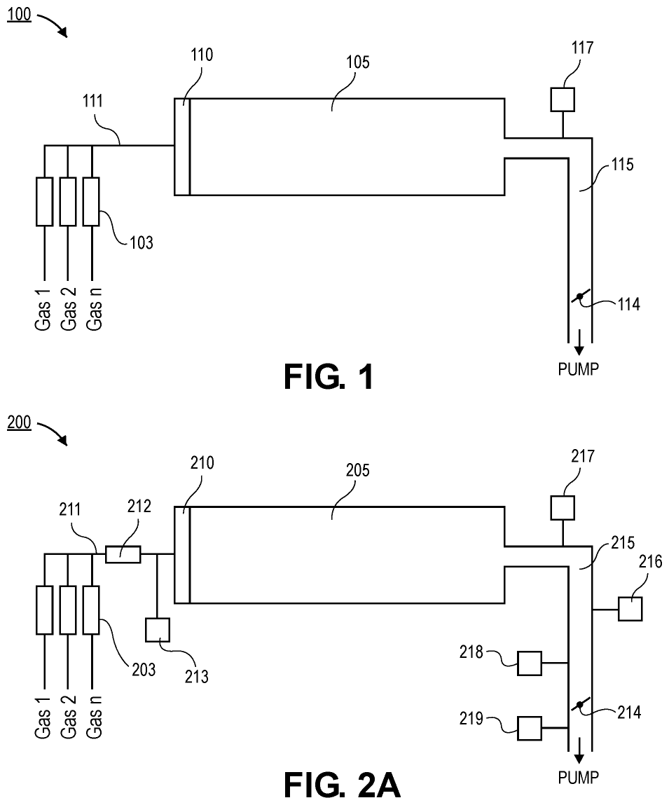

To provide context to embodiments of the present disclosure, a semiconductor processing tool 100 is shown in FIG. 1. The semiconductor processing tool 100 may comprise a chamber 105. A gas supply system may feed processing gasses into the chamber 105. For example, the gasses (e.g., Gas 1 to Gas n) may be flown into an input line 111 that feeds a gas cartridge 110 that regulates flow of the gas into the chamber 105. Control of the gas flow is dictated by mass flow controllers (MFCs) 103. The pressure within the chamber 105 is measured by a pressure gauge 117. Conditions within the chamber 105 are controlled by modulating the MFCs 103 and targeting a desired pressure read by the pressure gauge 117. That is, the MFCs 103 and the pressure gauge 117 may be considered as control loop sensors since the state of the MFCs 103 and the pressure gauge 117 dictate the process conditions within the chamber 105. However, the control loop sensors are not infallible. Often, the control loop sensors drift (i.e., become miscalibrated). As such, the processing tool 100 will tend to drift as well. Drift of the processing tool 100 results in wafer outcomes that are non-uniform between wafers. To avoid such non-uniformities, the processing tool 100 needs periodic qualification and tuning implemented by a process engineer or other user.

In addition to the tendency to drift, the control loop sensors do not provide all of the needed data that can be used to optimize process outcomes. For example, in a radical oxidation process (sometimes referred to as a “radox process” for short), it is desirable to know the velocity of the gas exiting the cartridge, the composition of the gasses exiting the cartridge, and the temperature within the chamber, among other parameters.

Accordingly, embodiments disclosed herein utilize a semiconductor processing tool that further comprises a set of witness sensors. The witness sensors are outside of the control loop. As such, the witness sensors may be used to monitor the control loop sensors. As the control loop sensors drift, changes to witness sensor outputs can be identified to alert the process engineer of the drifting conditions, even if the control loop sensors do not indicate any change in the process conditions.

Additionally, data from the witness sensors can be leveraged to provide virtual sensor data. Virtual sensor data may include the calculation of various in chamber process conditions that cannot be directly measured by physical sensors. Virtual sensor data may be obtained from calculations using the output of witness sensors and/or control loop sensors. For example, in a radox process, readings from witness sensors (e.g., a mass flow meter (MFM) and a pressure sensor upstream of the cartridge) and the chamber pressure sensor may be used as inputs to a Bernoulli equation to calculate the flow rate across the orifice of the inlet of the cartridge.

Furthermore, embodiments disclosed herein may include comparing witness sensor outputs with virtual witness sensor outputs calculated by a data model of the semiconductor processing tool. The data model may comprise a statistical model, a physical model of the physical processing tool, or a combination of a statistical model and a physical model. The data model represents a virtual twin of the physical processing tool. That is, for a given set of inputs into the physical processing tool and the data model, the outputs of the physical processing tool should match the outputs of the data model.

As such, when one or more virtual witness sensor outputs differs from one or more witness sensor outputs, it can be determined that the physical chamber has drifted. In such instances, the witness sensor outputs may be fed back into the data model as a learning data set in order to provide an updated data model. The updated data model may then be queried to generate a modified set of process inputs that will return the process chamber back to a desired process window.

In some embodiments where the virtual witness sensor data substantially matches the witness sensor data, further investigation may be used to double check the uniformity between the data model and the physical processing tool. For example, when the virtual witness sensor data matches the witness sensor data, it can be considered that additional calculated values of the data model are also correct. For example, additional virtual metrology calculated by the data model, such as, but not limited to film deposition rate, film composition, etc., can be compared to physical metrology data obtained from physical wafers. If the physical metrology data matches the virtual metrology data, the data model is confirmed. If the physical metrology data differs from the virtual metrology data, then the physical metrology data can be fed back into the data model as a learning data set in order to provide an updated data model. The updated data model may then be queried to generate a modified set of process inputs that will return the process chamber back to a desired process window.

The use of a semiconductor processing tool that utilizes witness sensors and/or a data model provides several benefits in the manufacturing environment. For example, instances of the processing tool going out of calibration and misprocessing wafers are reduced. Additionally, unnecessary downtime due to recalibration and tuning is avoided. Embodiments may also be used to design new processes for the processing tool more efficiently.

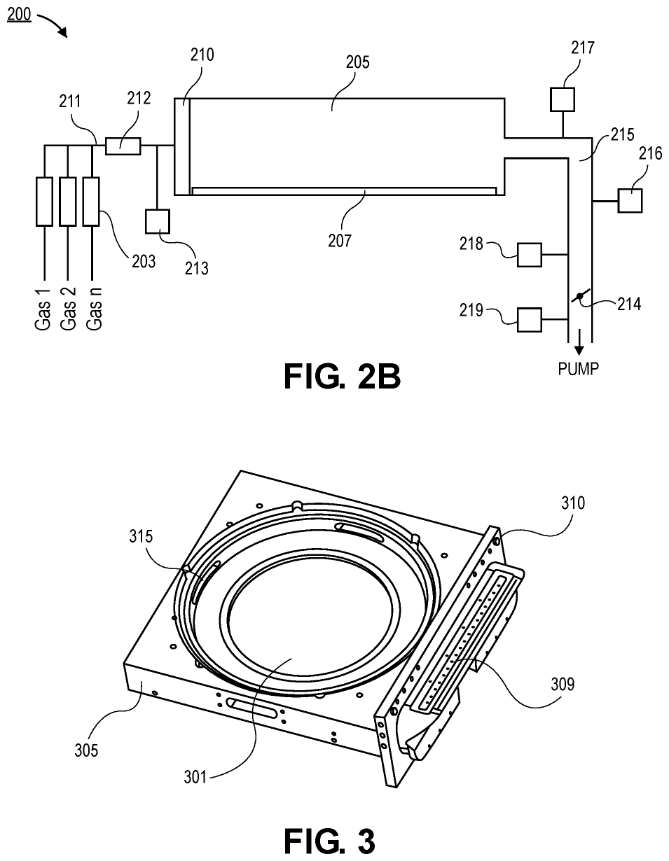

Referring now to FIG. 2A, a block diagram of a semiconductor processing tool 200 is shown, in accordance with an embodiment. In the illustrated embodiment, the processing tool 200 is described as a radical oxidation tool. However, it is to be appreciated that embodiments disclosed herein may be suitable for use in other types of processing tools, such as, but not limited to, plasma etching or deposition chambers.

In an embodiment, the processing tool 200 comprises a chamber 205. The chamber 205 may be a chamber suitable for providing a sub-atmospheric pressure in which a substrate (e.g., a semiconductor wafer) is processed. In an embodiment, the chamber 205 may be sized to accommodate a single substrate or a plurality of substrates. Semiconductor substrates suitable for processing in the chamber 205 may include silicon substrates, or any other semiconductor substrate. Other substrates, such as glass substrates, may also be processed in the chamber 205.

In an embodiment, a gas distribution network feeds gas from one or more gas sources (e.g., Gas 1, Gas 2, Gas n, etc.) to a cartridge 210. In a particular embodiment the gas sources may comprise one or more of oxygen, hydrogen, and nitrogen. While three gas sources are shown in FIG. 2A, it is to be appreciated that embodiments may include one or more gas sources. The cartridge 210 may include an inlet for receiving gas from line 211 and outlets for distributing the gas into the chamber 210. In the illustrated embodiment, the cartridge 210 is shown as feeding the gas into the chamber from a side of the chamber 210. However, it is to be appreciated that the cartridge 210 may optionally feed the gas into the chamber from above or below the chamber. In some embodiments, the cartridge 210 may also be referred to as a showerhead, particularly in cases where the processing tool is a plasma generating tool.

In an embodiment, the flow of each of the processing gasses may be controlled by separate MFCs 203. In an embodiment, the MFCs 203 may be part of the control loop sensor group. The MFCs 203 control the flow of gas into a input line 211. In an embodiment, a mass flow meter (MFM) 212 is provided on the upstream side of the cartridge 210. The MFM 212 allows for the actual flow from the source gasses to be measured. Also included on the upstream side of the cartridge 210 is a pressure gauge 213. The pressure gauge 213 allows for the pressure of the input line 211 to be measured. The MFM 212 and the pressure gauge 213 may be considered witness sensors since they are outside of the control loop.

In an embodiment, a chamber pressure gauge 217 may be provided to measure a pressure in the chamber 205. The chamber pressure gauge 217 may be part of the control loop sensor group. In an embodiment, additional witness sensors are provided along an exhaust line 215 of the processing tool 200. The additional sensors may comprise a leak detection sensor 216, and additional pressure gauges 218 and 219. The leak detection sensor 216 may include a self-contained plasma optical emission spectroscopy (OES) device to measure oxygen that leaks into the chamber 205. The pressure gauges 218 and 219 may be on an upstream side and a downstream side of a throttle valve 214, respectively.

In an embodiment, the pressure gauges 213, 217, 218, and 219 may have operating ranges that are suitable for the typical pressures provided at the locations within the processing tool where they are located. For example, the pressure gauge 213 may operate at a pressure range that is higher than the pressure ranges of the other pressure gauges 217, 218, and 219. Similarly, the pressure gauge 218 may operate at a pressure range that is higher than the pressure range of the pressure gauge 219. In a particular embodiment, the pressure gauge 217 may operate at a range including 1,000 T, the pressure gauge 217 may operate at a range including 20 T, the pressure gauge 218 may operate at a range including 100 T, and the pressure gauge 219 may operate at a range including 10 T.

In an embodiment, the witness sensors (e.g., 212, 213, 216, 218, and 219) may be used to provide monitoring of chamber drift. For example, the control loop sensors (e.g., 203 and 217) may become miscalibrated during use of the processing tool 200. As such, the readings of the control loop sensors 203, 217 may remain constant while the outcome on the wafer (e.g., deposition rate of a film) changes. In such an instance, the outputs of the witness sensors will change to indicate that the chamber has drifted.

In an additional embodiment, the witness sensors may be leveraged to implement virtual sensors in the chamber 205. Virtual sensors may refer to a sensor that provides outputs that are computationally generated, as opposed to direct readings of a physical value (as is the case for physical sensors). Virtual sensors are therefore powerful for determining conditions within the processing tool 200 that are difficult or impossible to measure with conventional physical sensors.

In one embodiment, a virtual sensor may be used to determine a flow rate of processing gasses at the exit of the cartridge 210. Calculating the flow rate at the cartridge 210 is a valuable metric that can be used to control the deposition rate and/or deposition uniformity of a film on the wafer. In a particular embodiment, the flow rate at the cartridge 210 may be calculated using a Bernoulli equation with the variables supplied by using the outputs of the MFM 212, the pressure gauge 213, the pressure gauge 217, and the known geometry of the cartridge 210. While an example of flow rate at the cartridge is provided, it is to be appreciated that other unknowns within the processing tool 200 may be determined using virtual sensor calculations. For example, unknowns such as, but not limited to gas composition at various locations in a chamber, deposition rate across a wafer, pressure across a wafer, and film composition across a wafer may be determined using virtual sensor implementations.

Referring now to FIG. 2B, a diagram of a processing tool 200 is shown, in accordance with an additional embodiment. In the illustrated embodiment, the processing tool 200 in FIG. 2B may be substantially similar to the processing tool 200 in FIG. 2A, with the exception that an array of temperature sensors 207 are provided in the chamber 205. For example, the temperature sensors 207 may be thermocouples or the like. In an embodiment, the temperature sensors 207 may be provided on a reflector plate (not shown) of the chamber. The temperature sensors 207 may be considered witness sensors in some embodiments. That is, the temperature sensors 207 may be outside of the control loop.

Temperature sensors 207 may provide an additional known variable to enable more extensive virtual sensor implementations. In an embodiment, the temperature sensors 207 may also be used in determining when a steady state has been reached in the chamber 205. This is particularly beneficial when bringing the processing tool 200 up from a cold state, such as ramping up the processing tool 200 after a maintenance event. For example, the output of the temperature sensors 207 in combination with one or more pressure gauges 213, 217, 218, and 219, and the angle of the throttle valve may be monitored, and the chamber can be ready for use when a steady state of the various sensors is reached. In an embodiment, monitoring when the chamber reaches a steady state is useful because it eliminates the scrap or rework of wafers typically experienced due to first wafer effects in a processing tool.

Referring now to FIG. 3, a perspective view illustration of a processing tool 300 is shown, in accordance with an embodiment. The processing tool 300 is an illustration of a radical oxidation tool 300. However, it is to be appreciated that other types of processing tools may be used in accordance with embodiments disclosed herein.

In an embodiment, the processing tool 300 comprises a chamber 305. A wafer 301 may be disposed in the chamber 305. The wafer 305 may be inserted into the chamber 305 through a slit valve 309 or the like. As shown, a cartridge 310 or other gas distribution plate is provided proximate to the slit valve 309, and flows gas into the chamber 305 from the side. In an embodiment, an exhaust 315 is provided on an opposite end of the chamber 305 from the cartridge 310. However, it is to be appreciated that more than one exhaust 315 may be used, and the location of the exhaust may be at other locations within the chamber 305.

In an embodiment, the semiconductor processing tools described herein may include a physical processing tool (such as the processing tools described above) and a digital twin of the physical processing tool. The digital twin may comprise a data model that is developed using machine learning. Ideally, when a set of process inputs (e.g., hardware parameters and/or process parameters) is provided into the physical processing tool and into the data model, the outcome on a physical wafer will match the outcome on a virtual wafer. Such a processing tool is beneficial because it allows for chamber drift to be determined. Additionally, when chamber drift is detected, the data model can be updated and queried to determine a new set of process inputs that return subsequent processing outcomes back into a desired process window.

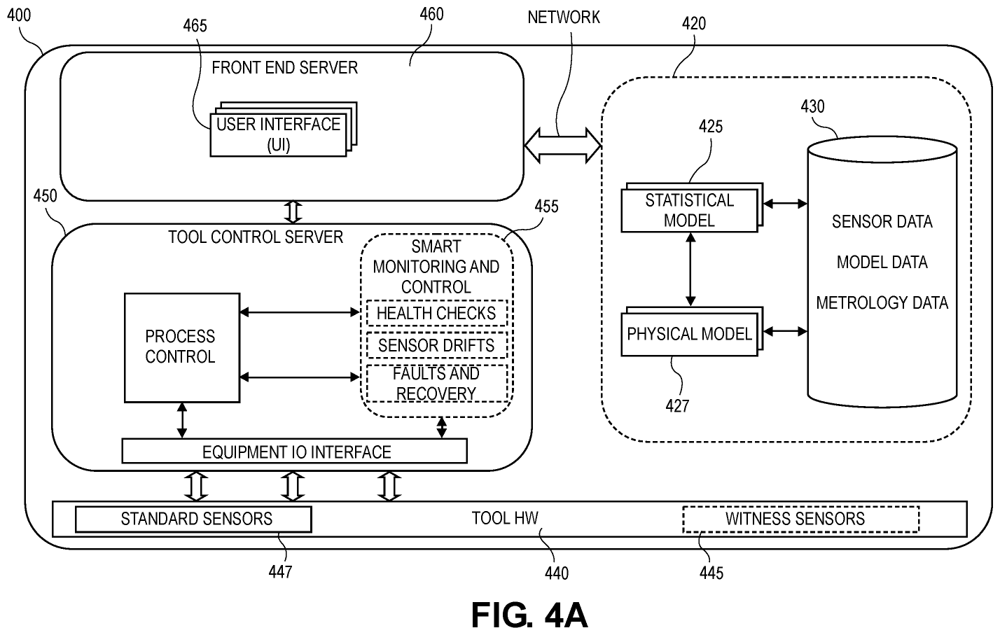

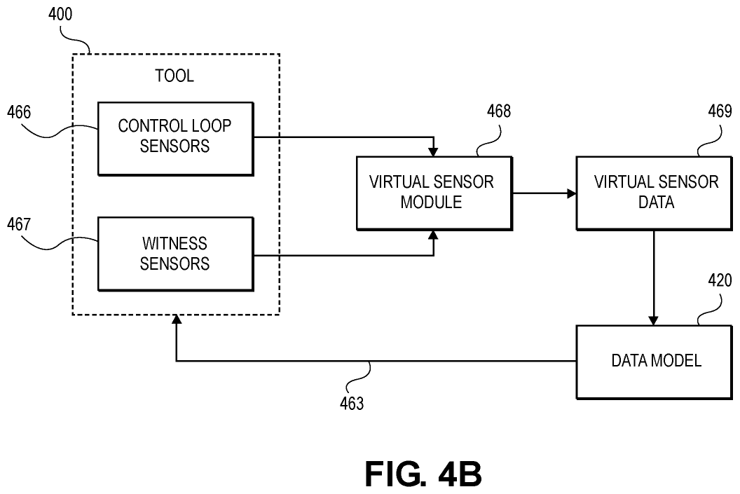

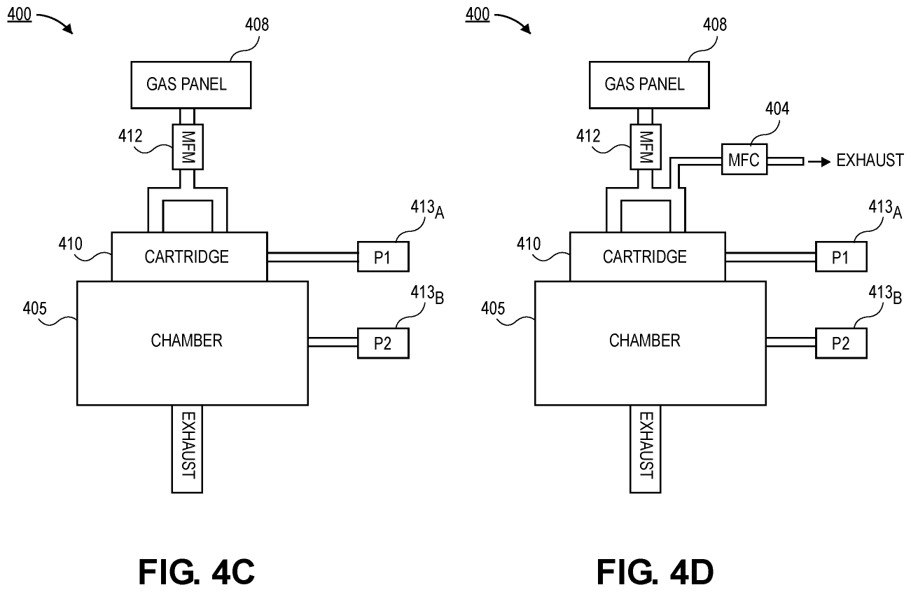

Referring now to FIG. 4A, a schematic of a processing tool 400 is shown, in accordance with an embodiment. As shown, a data model server 420 may be integrated with the processing tool 400. For example, the data model server 420 may be communicatively coupled to a front end server 460 by a network connection, as indicated by the arrow. However, in other embodiments, the data model server 420 may be external to the processing tool 400. For example, data model server 420 may be communicatively coupled to the processing tool 400 through an external network or the like.

In an embodiment, the data model server 420 may comprise one or both of a physical model 427 and a statistical model 425. The statistical model 425 and the physical model 427 may be communicatively coupled to a database 430 for storing input data (e.g., sensor data, model data, metrology data, etc.) used to build and/or update the statistical model 425 and the physical model 427. In an embodiment, the statistical model 425 may be generated by implementing a physical design of experiment (DoE) and use interpolation to provide an expanded process space model. In an embodiment, the physical model 427 may be generated using real world physics and chemistry relationships. For example, physics and chemistry equations for various interactions within a processing chamber may be used to build the physical model. In an embodiment, the processing tool 400 may comprise a front end server 460, a tool control server 450, and tool hardware 440. The front end server 460 may comprise a user interface 465 for the data model server 420. The user interface 465 provides an interface for a process engineer to utilize the data modeling in order to execute various operations, such as recipe drift monitoring, as will be described in greater detail below.

The tool control server 450 may comprise a smart monitoring and control block 455. The smart monitoring and control block 455 may comprise modules for providing diagnostics and other monitoring of the processing tool 400. Modules may include, but are not limited to health checks, sensor drift, fault recovery, and leak detection. The smart monitoring and control block 455 may receive data from various sensors implemented in the tool hardware as inputs. The sensors may include standard sensors 447 that are generally present in semiconductor manufacturing tools 400 to allow for operation of the tool 400. For example, the sensors 447 may include control loop sensors such as those described above. The sensors may also include witness sensors 445 that are added into the tool 400. The witness sensors 445 provide additional information that is necessary for the building of highly detailed data models. For example, the witness sensors may include physical sensors and/or virtual sensors. As noted above, virtual sensors may utilize the data obtained from two or more physical sensors and use calculations in order to provide additional sensor data not obtainable from physical sensors alone. In a particular example, a virtual sensor may utilize an upstream pressure sensor and a downstream pressure sensor in order to calculate a flow rate through a portion of the processing tool, such as a gas cartridge. Generally, witness sensors may include any type of sensor, such as, but not limited to, pressure sensors, temperature sensors, and gas concentration sensors. In an embodiment, the smart monitoring and control block 455 may provide data that is used by the data model server 420. In other embodiments, output data from the various witness sensors 445 may be provided directly to the data model server 420.

Referring now to FIG. 4B, a schematic illustrating how the various sensors are used to provide feedback control to the tool 400 is shown, in accordance with an embodiment. As shown, the tool 400 may comprise one or more control loop sensors 466 and one or more witness sensors 467. Sensor data from the one or more control loop sensors 466 and the one or more witness sensors 467 may be fed to a virtual sensor module 468. The virtual sensor module 468 may implement calculations on the sensor data to provide virtual sensor data 469. For example, the virtual sensor module 468 may implement Bernoulli's Equation for a Venturi type sensor in order to calculate an accurate process gas flow at one or more locations in the chamber (e.g., at the exit of the cartridge into the chamber and/or at the exhaust). As will be described below in greater detail, knowledge of the process gas flows allows for greater control of on wafer uniformity.

In an embodiment, the virtual sensor data 469 may then be fed to the data model server 420. However, in some embodiments, the virtual sensor module 468 may be implemented as part of the data model server 420. The data model server 420 may utilize the process gas flows as a best known flow that can be used to better control, predict, find drifts, find faults, and the like. These multiple variables (i.e., sensor data outputs and virtual data outputs) can be used as inputs and training for the data model and are more effective than using single point sensors. In an embodiment, the data model server 420 may output a control effort 463 that modifies one or more process parameters in the tool 400 in order to correct drift and bring the tool 400 back into a desired process window.

In an embodiment, such feedback control operations may be implemented for many different types of virtual sensor data. In a particular embodiment, as described above, process gas flows may be calculated and used to control the tool output. However, embodiments are not limited to process gas flows. For example, virtual sensors may also be utilized to provide gas compositions at various locations in the chamber, wafer temperature uniformity, or other process variables that cannot be directly (or easily) measured with physical sensors. Generally, the overall effect of using virtual sensors to inform the data model and provide feedback control of the tool is to significantly better control the process. Additionally, it is possible to optimize the data learning rate of an intelligent system, such as those described herein, by providing additional data that is not capable of being provided with physical sensors alone. The multiplicity of inputs, along with the many directions of cross-checking, including expectations of learning in the chamber specific digital twin, leads to a more antifragile system.

Referring now to FIGS. 4C and 4D, schematic illustrations of a processing tool 400 that is configured to control process gas velocity at the entrance to the chamber 405 (i.e., at the exit of the cartridge 410) are shown, in accordance with an embodiment. In an embodiment, the process gas velocity may be calculated (as a virtual sensor output) using the sensor data from the MFM 412, pressure sensor 413A and pressure sensor 413E as inputs to a Bernoulli equation. Generally, higher velocities move the flame front further away from the cartridge 410, and lower velocities move the flame front closer to the cartridge 410. As those skilled in the art will recognize, the position of the flame front affects the process uniformity. The position of the flame front that will provide the optimum process uniformity for a given chamber may be calculated using the data model server 420. That is, the data model server 420 is able to calculate the optimum pressure deltas for a desired process uniformity profile.

Control of the pressure deltas may be implemented by any suitable control of the tool 400. For example, in FIG. 4C the pressure may be modulated by changing the total flow from the gas panel 408. The total flow from the gas panel 408 may be controlled by changes to mass flow controllers (not shown) that regulate the flow of gas out of the gas panel 408. In an embodiment, the mass flow controllers are controlled in a manner so that the ratio of the process gasses (e.g., the ratio of hydrogen gas to oxygen gas) remains constant. In an additional embodiment, as shown in FIG. 4D, a back pressure controller or mass flow controller 404 may be provided at the entrance to the cartridge 410. The mass flow controller 404 may be used to bleed off excess flow and servo the cartridge pressure to obtain the needed delta pressure between the cartridge 410 and the chamber 405.

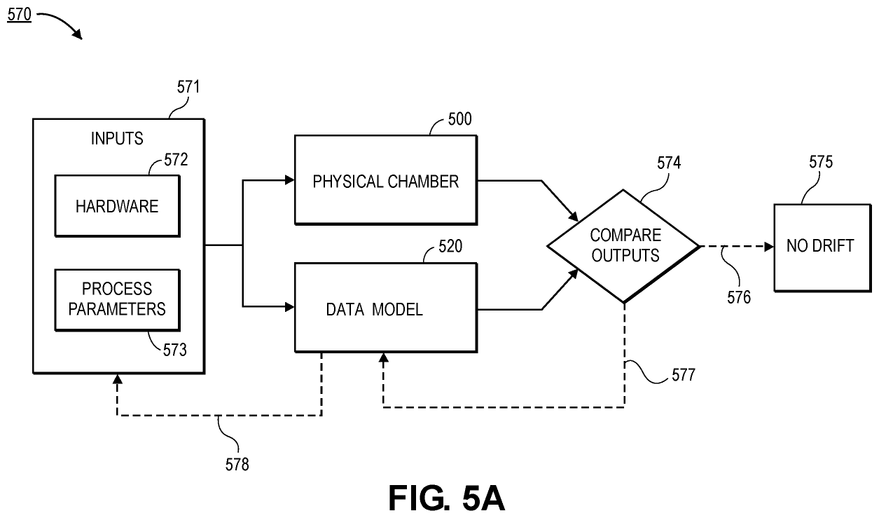

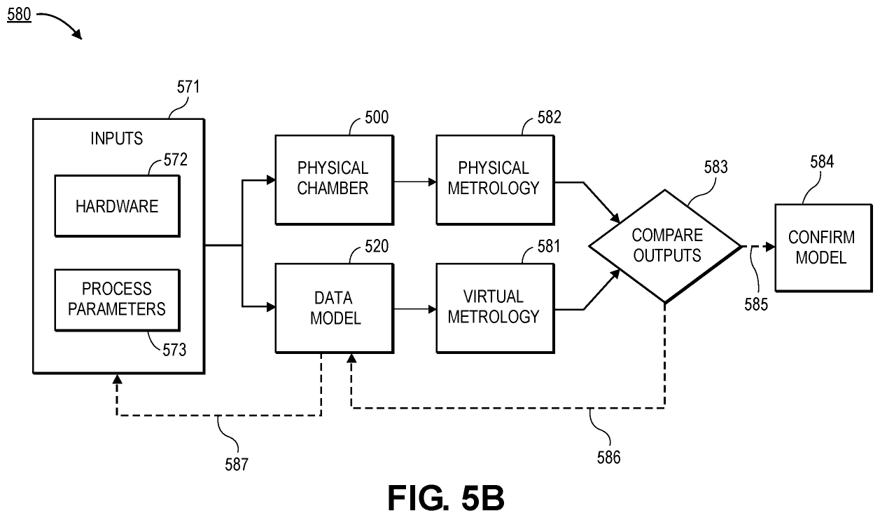

Referring now to FIG. 5A, a flowchart 570 of a process for utilizing a data model 520 in conjunction with the physical chamber 500 to detect chamber drift is provided, in accordance with an embodiment. In an embodiment, the data model 520 has been calibrated (e.g., through machine learning) so that it is presumed that the data model 520 serves as a digital twin of the physical chamber 500. That is, when there is no drift in the physical chamber 500, outputs of the data model 520 are expected to match the outputs of the physical chamber 500.

In an embodiment, flowchart 570 may begin with providing inputs 571 into the physical chamber 500 and the data model 520. The inputs 571 may include hardware inputs 572 and/or process parameter inputs 575. Examples of hardware inputs 572 include, but are not limited to, hole sizes of the cartridge, other cartridge geometry, and chamber geometry. For example, cartridges with different geometries may swapped into the chamber 500 to change the hardware input 572 of the physical chamber. Examples, of process parameter inputs 575 include, but are not limited to pressure, flow rates of processing gasses, and temperature.

At block 574, the one or more outputs of the physical chamber and one or more outputs of the data model 520 are compared. The outputs that are compared may include sensor data (e.g., control loop sensor data, witness sensor data, and/or virtual sensor data). When the outputs of the data model 520 (e.g., virtual control loop sensor data, virtual witness sensor data, and virtual sensor data) substantially match the outputs of the chamber 500, decision branch 576 is chosen and it is determined that there is no drift in the chamber 500.

When one or more of the outputs of the data model 520 are different than one or more of the outputs of the chamber 500, it can be determined that the chamber 500 has drifted. When chamber drift is detected branch 577 is taken. In branch 577, the one or more chamber outputs from the physical chamber 500 are fed back into the data model 520 as a learning data set to provide an updated data model 520. Taking in the learning data set allows for the updated data model to more accurately model the drifted chamber 500. After the updated data model 520 is generated, the updated data model 520 may be queried for new inputs that will drive the drifted physical chamber 500 back into a desired process window. The new inputs are fed back into the input block 571 as indicated by branch 578.

The process illustrated in FIG. 5A may then repeat any desired number of times. In an embodiment, the comparison block 574 may be implemented after every wafer is processed. Since the comparison does not require the use of metrology, it is feasible to implement the comparison block 574 more frequently. In other embodiments, the comparison block 574 may be implemented at regular intervals or at any desired frequency. For example, comparison block 574 may be implemented with a higher frequency at the ramp up of a process compared to after the chamber 500 has reached a substantially steady state.

Referring now to FIG. 5B a flowchart 580 of a process for performing a secondary check to confirm the accuracy of a data model 520 is shown, in accordance with an embodiment. In FIG. 5B, the data model 520 has been confirmed to not have drift, e.g., using a method such as the method described in FIG. 5A. That is, the virtual witness sensor outputs substantially match the witness sensor data of the physical chamber for a given set of inputs 571. While the physical witness sensor data and the virtual witness sensor data may substantially match, the wafer outcomes may still be different. The method of flowchart 580 allows for a comparison of physical wafer outcomes to virtual wafer outcomes.

When the virtual witness sensor outputs match the witness sensor data, it can be considered that additional calculated values of the data model 520 are also correct. The additional calculated values may include virtual metrology 581, such as, but not limited to film deposition rate, film composition, or any other characteristic that is typically determined using metrology inspection. In order to confirm the data model 520, the virtual metrology 581 calculated by the data model 520 can be compared to physical metrology 582 obtained from physical wafers that were processed in the physical chamber 500.

At block 583, the virtual metrology 581 is compared to the physical metrology 582. If the physical metrology data 582 matches the virtual metrology data 581, branch 585 is taken, and the data model 520 is confirmed at block 584. If the physical metrology data 582 differs from the virtual metrology data 581, then branch 586 is taken, and the physical metrology data 582 is fed back into the data model 520 as a learning data set in order to provide an updated data model. The updated data model may then be queried to generate a modified set of process inputs that will return the process chamber 500 back to a desired process window. The new inputs are fed back into the input block 571 as indicated by branch 587.

In an embodiment, the process in flowchart 580 may be implemented at any desired frequency. However, since physical metrology is a time and resource intensive process, embodiments may implement the process in flowchart 580 less frequently than the process in flowchart 570. For example, the process in flowchart 580 may be implemented once per lot, once per planned maintenance, or once it is believed that a steady state of the chamber 500 has been reached.

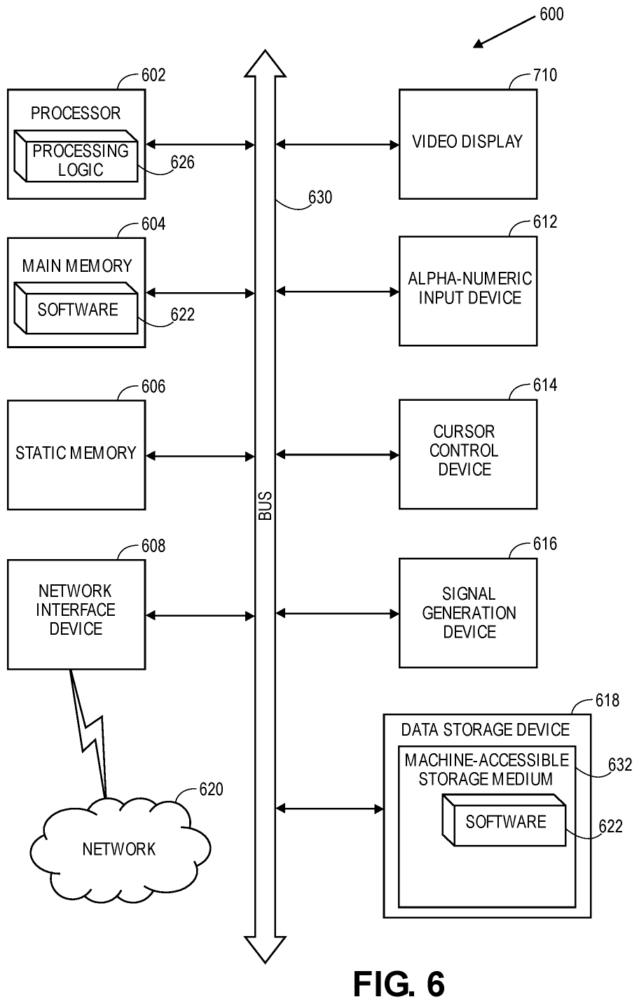

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), MRAM, etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 632 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of processing a wafer using insight from a data model and/or a method of updating or building a data model.

Thus, methods for using a data model for processing wafers in a processing tool have been disclosed.

What is claimed is:

1. A processing tool, comprising:
a chamber;
a cartridge for flowing one or more processing gasses into the chamber from a plurality of gas sources;
a mass flow controller for each of the plurality of gas sources;
a mass flow meter between the gas sources and the cartridge;
a first pressure gauge between the mass flow meter and the cartridge;
a second pressure gauge fluidically coupled to the chamber; and
an exhaust line coupled to the chamber.

2. The processing tool of claim 1, further comprising:
an array of temperature sensors on a reflector in the chamber.

3. The processing tool of claim 1, further comprising:
a throttle valve in the exhaust line;
a third pressure gauge in the exhaust line between the throttle valve and the chamber; and
a fourth pressure gauge in the exhaust line on an opposite side of the throttle valve from the third pressure gauge.

4. The processing tool of claim 3, wherein the first pressure gauge is optimized to detect pressure in a first pressure range, wherein the third pressure gauge is optimized to detect pressure in a second pressure range, wherein the fourth pressure gauge is optimized to detect pressure in a third pressure range, and wherein the first pressure range has a maximum pressure that is greater than a maximum pressure of the second pressure range, and wherein the maximum pressure of the second pressure range is greater than a maximum pressure of the third pressure range.

5. The processing tool of claim 1, wherein the processing tool implements a radical oxidation process.

6. The processing tool of claim 5, wherein the plurality of gas sources comprise an oxygen source gas and a hydrogen source gas.

7. The processing tool of claim 1, wherein the cartridge injects gas into the chamber from a side of the chamber.

8. The processing tool of claim 1, wherein the cartridge and the exhaust line are on opposite ends of the chamber.

9. A processing tool, comprising:
a physical tool, wherein the physical tool comprises:
control loop sensors; and
witness sensors;
a virtual sensor module, wherein the virtual sensor module receives control loop sensor data and witness sensor data as inputs, and wherein the virtual sensor module outputs virtual sensor data; and
a data model, wherein the data model comprises:
a statistical model; and
a physical model, wherein the virtual sensor data is provided to the data model, and wherein the data model is configured to provide a control effort to the physical tool based, at least in part, on the virtual sensor data.

10. The processing tool of claim 9, wherein the physical tool is a tool for implementing a radical oxidation process.

11. The processing tool of claim 10, wherein the control loop sensors comprise:
mass flow controllers for source gasses and a first pressure gauge for measuring a pressure in a chamber of the processing tool; and
wherein the witness sensors comprise:
a mass flow meter;
a second pressure gauge between the mass flow meter and the chamber;
a third pressure gauge on an upstream side of an exhaust line; and
a fourth pressure gauge on a downstream side of the exhaust line, wherein a throttle valve is between the third pressure gauge and the fourth pressure gauge.

12. The processing tool of claim 11, wherein outputs from the mass flow meter, the second pressure gauge, and the first gauge are fed to the virtual sensor module, and wherein the virtual sensor module outputs a process gas flow rate at an entrance to the chamber.

13. The processing tool of claim 12, wherein the virtual sensor module utilizes a Bernoulli equation to determine the process gas flow rate.

14. The processing tool of claim 10, wherein the witness sensors further comprise an array of temperature sensors on a reflector plate in the chamber.

15. The processing tool of claim 9, wherein the virtual sensor outputs provide a measure of one or more of a process gas velocity across the wafer, a pressure across the wafer, an oxygen concentration across the wafer, a hydrogen concentration across the wafer, a wafer temperature, a wafer temperature uniformity, and a deposition rate across the wafer.

16. A method of determining chamber drift, comprising:
providing hardware inputs and process parameter inputs into a physical chamber and a data model;
collecting witness sensor outputs from the physical chamber;
generating virtual witness sensor outputs from the data model; and
comparing the witness sensor outputs with the virtual witness sensor outputs.

17. The method of claim 16, wherein the witness sensor outputs are fed back into the data model to form an updated data model when the witness sensor outputs are different than the virtual witness sensor outputs.

18. The method of claim 17, further comprising:
querying the updated data model for modified inputs to return the witness sensor outputs to a targeted process window.

19. The method of claim 16, wherein when the witness sensor outputs substantially match the virtual witness sensor outputs, the method further comprises:
performing metrology on a processed wafer to provide metrology outputs; and
comparing virtual metrology outputs from the data model with the metrology outputs.

20. The method of claim 19, wherein when the metrology outputs are different than the virtual metrology outputs, the metrology outputs are fed back into the data model to provide an updated data model.
